(19) United States
(12) Patent Application Publication
(10) Pub. No.: US 2025/0105863 A1
(43) Pub. Date: Mar. 27, 2025

(54) RADIO-FREQUENCY CIRCUIT AND COMMUNICATION DEVICE

(71) Applicant: Murata Manufacturing Co., Ltd., Nagaokakyo-shi (JP)

(72) Inventor: Yuji TAKEMATSU, Nagaokakyo-shi (JP)

(73) Assignee: Murata Manufacturing Co., Ltd., Nagaokakyo-shi (JP)

(21) Appl. No.: 18/976,378

(22) Filed: Dec. 11, 2024

Related U.S. Application Data
(63) Continuation of application No. PCT/JP2023/011547, filed on Mar. 23, 2023.

(30) Foreign Application Priority Data
Jun. 15, 2022 (JP) 2022-096554

(51) Int. Cl. H04B 1/04; H04B 1/00

(52) U.S. Cl. CPC H04B 1/04; H04B 1/0078; H04B 2001/0408

(57) ABSTRACT

A radio-frequency circuit includes a power amplifier configured to output a first maximum transmit power, a power amplifier configured to output a second maximum transmit power that is higher than the first maximum transmit power, a filter having a pass band that includes a band A, a filter having a pass band that includes a band B different from the band A, a switch coupled between the power amplifier and the filter and between the power amplifier and the filter, and a switch coupled between the switch and the filter and between the power amplifier and the filter.

### CROSS-REFERENCE TO RELATED APPLICATIONS

This is a continuation application of PCT/JP2023/011547, filed on Mar. 23, 2023, designating the United States of America, which is based on and claims priority to Japanese Patent Application No. JP 2022-096554 filed on Jun. 15, 2022. The entire contents of the above-identified applications, including the specifications, drawings and claims, are incorporated herein by reference in their entirety.

### TECHNICAL FIELD

The present disclosure relates to a radio-frequency circuit and a communication device.

### BACKGROUND ART

Patent Document 1 (FIG. 8) discloses a power amplifier system including a first power amplifier and a second power amplifier, a first switch coupled to the output end of the first power amplifier, a first signal path coupled between the first switch and a first antenna, a second signal path coupled between the first switch and a second antenna, and a third signal path coupled to the output end of the second power amplifier and the second antenna. In the power amplifier system, assuming signals in a first frequency band are exclusively transmitted, the signals in the first frequency band are amplified by the first power amplifier and transferred through the first signal path. Assuming signals in a second frequency band are exclusively transmitted, the signals in the second frequency band are amplified by the second power amplifier and transferred through the third signal path. Assuming signals in the first frequency band and the second frequency band are simultaneously transmitted, the signals in the first frequency band are amplified by the first power amplifier and transferred through the first signal path, and the signals in the second frequency band are amplified by the second power amplifier and transferred through the third signal path.

### CITATION LIST

### Patent Document

Patent Document 1: Japanese Unexamined Patent Application Publication No. 2022-13725

### SUMMARY OF DISCLOSURE

### Technical Problem

However, the power amplifier system (radio-frequency circuit) disclosed in Patent Document 1 has problems such as difficulty in optimizing power efficiency when amplifying radio-frequency signals in different frequency bands.

It is therefore an feature of the present disclosure to provide a radio-frequency circuit and a communication device that optimize power efficiency when amplifying radio-frequency signals in different frequency bands.

### Solution to Problem

To achieve the feature described above, a radio-frequency circuit according to an embodiment of the present disclosure includes a first power amplifier configured to output a first maximum transmit power, a second power amplifier configured to output a second maximum transmit power that is higher than the first maximum transmit power, a first filter having a pass band that includes a first band, a second filter having a pass band that includes a second band different from the first band, a first switch coupled between the first power amplifier and the first filter and between the first power amplifier and the second filter, and a second switch coupled between the first switch and the second filter and between the second power amplifier and the second filter.

### Advantageous Effects of Disclosure

The present disclosure provides a radio-frequency circuit and a communication device that optimize power efficiency when amplifying radio-frequency signals in different frequency bands.

### BRIEF DESCRIPTION OF DRAWINGS

FIG. 1 is a circuit configuration diagram of a radio-frequency circuit and a communication device according to an embodiment.

FIG. 2A illustrates the circuit state of the radio-frequency circuit according to the embodiment assuming band-A signals are exclusively transmitted.

FIG. 2B illustrates the circuit state of the radio-frequency circuit according to the embodiment assuming band-B signals are exclusively transmitted.

FIG. 2C illustrates the circuit state of the radio-frequency circuit according to the embodiment assuming band-A signals and band-B signals are simultaneously transmitted.

FIG. 3 is a circuit configuration diagram of a radio-frequency circuit and a communication device according to a comparative example.

FIG. 4 is a circuit configuration diagram of a radio-frequency circuit and a communication device according to a modification.

FIG. 5 illustrates the circuit state of the radio-frequency circuit according to the modification assuming 2G signals are transmitted.

### DESCRIPTION OF EMBODIMENTS

Hereinafter, embodiments of the present disclosure will be described in detail with reference to the drawings. It should be noted that the embodiments described below provide comprehensive or specific examples. Details such as numerical values, shapes, materials, constituent elements, and arrangements and connection modes of the constituent elements provided in the following embodiments are illustrative and are not intended to limit the present disclosure.

The drawings are schematically illustrated with necessary emphasis, omissions, or proportion adjustments to depict the present disclosure and do not necessarily represent exact details; thus, the shapes, positional relationships, and proportions can differ from actual implementations. Identical reference numerals are assigned to substantially the same configuration elements across the drawings, and redundant descriptions of these configuration elements can be omitted or simplified.

In the present disclosure, the term “couple” refers to a situation where a circuit element is directly connected to another circuit element by using a connection terminal and/or a wire line conductor, as well as to a situation where a circuit element is electrically connected to another circuit element via an additional circuit element. The expression “coupled between A and B” refers to a situation where a circuit element is connected to both A and B in a path that connects A and B.

In the present disclosure, the term “transmit path” refers to a transfer line formed by, for example, wire lines for transferring radio-frequency transmit signals, electrodes directly coupled to the wire line, and terminals directly coupled to the wire line or electrode. The term “receive path” refers to a transfer line formed by, for example, wire lines for transferring radio-frequency receive signals, electrodes directly coupled to the wire line, and terminals directly coupled to the wire line or electrode.

In the present disclosure, a first band (band A) and a second band (band B) represent frequency bands defined by, for example, standards organizations such as the 3rd Generation Partnership Project (3GPP (registered trademark)) and the Institute of Electrical and Electronics Engineers (IEEE)), for communication systems that are built using radio access technology (RAT). As the communication system in the present embodiment and modifications, for example, a 2nd Generation (2G) system, a 4th Generation Long Term Evolution (4G LTE) system, a 5th Generation New Radio (5G NR) system, or a Wireless Local Area Network (WLAN) system may be used, but these are not to be interpreted as limiting.

### Embodiment

### 1 Circuit Configuration of Radio-Frequency Circuit 1 and Communication Device 4

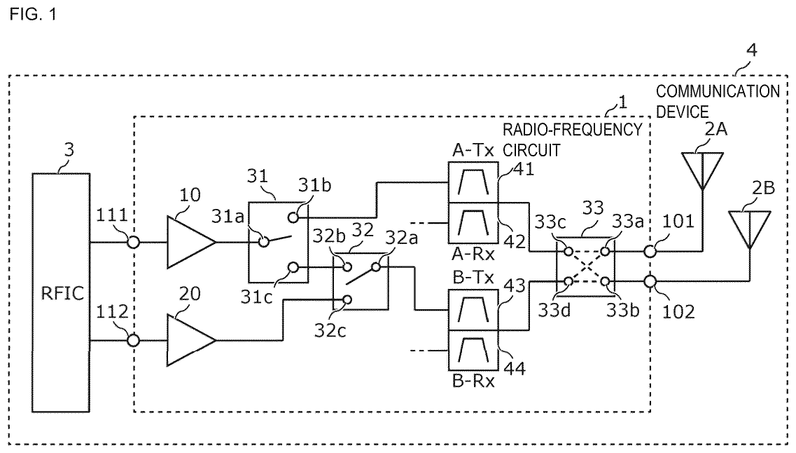

A circuit configuration of a radio-frequency circuit 1 and a communication device 4 according to the present embodiment will be described with reference to FIG. 1. FIG. 1 is a circuit configuration diagram of the radio-frequency circuit 1 and the communication device 4 according to the embodiment.

### [1.1 Circuit Configuration of Communication Device 4]

First, a circuit configuration of the communication device 4 will be described. As illustrated in FIG. 1, the communication device 4 according to the present embodiment includes the radio-frequency circuit 1, antennas 2A and 2B, and a radio-frequency (RF) signal processing circuit (RFIC) 3.

The radio-frequency circuit 1 is operable to transfer radio-frequency signals between the antennas 2A and 2B and the RFIC 3. A detailed circuit configuration of the radio-frequency circuit 1 will be described later.

The antenna 2A is coupled to an antenna connection terminal 101 of the radio-frequency circuit 1. The antenna 2A is operable to transmit radio-frequency signals outputted from the radio-frequency circuit 1 and to receive radio-frequency signals from outside and output the radio-frequency signals to the radio-frequency circuit 1.

The antenna 2B is coupled to an antenna connection terminal 102 of the radio-frequency circuit 1. The antenna 2B is operable to transmit radio-frequency signals outputted from the radio-frequency circuit 1 and to receive radio-frequency signals from outside and output the radio-frequency signals to the radio-frequency circuit 1.

The RFIC 3 is an example of a signal processing circuit for processing radio-frequency signals. Specifically, the RFIC 3 is operable to process, for example by up-conversion, transmit signals inputted from a baseband signal processing circuit (BBIC; not illustrated) and output the radio-frequency transmit signals generated by the signal processing to transmit paths in the radio-frequency circuit 1. The RFIC 3 is operable to process, for example by down-conversion, radio-frequency receive signals inputted through receive paths of the radio-frequency circuit 1 and output the receive signals generated by the signal processing. The RFIC 3 includes a control unit for controlling elements included in the radio-frequency circuit 1, such as switches and amplifiers. The function of the control unit of the RFIC 3 may be partially or entirely implemented outside the RFIC 3; for example, the function of the control unit of the RFIC 3 may be partially or entirely implemented in the BBIC or the radio-frequency circuit 1.

In the communication device 4 according to the present embodiment, the antennas 2A and 2B are non-essential constituent elements.

### [1.2 Circuit Configuration of Radio-Frequency Circuit 1]

Next, a circuit configuration of the radio-frequency circuit 1 will be described. As illustrated in FIG. 1, the radio-frequency circuit 1 includes power amplifiers 10 and 20, filters 41, 42, 43, and 44, switches 31, 32, and 33, the antenna connection terminals 101 and 102, and radio-frequency input terminals 111 and 112.

The antenna connection terminal 101 is an external connection terminal included in the radio-frequency circuit 1 and is coupled to the antenna 2A. The antenna connection terminal 102 is an external connection terminal included in the radio-frequency circuit 1 and is coupled to the antenna 2B. The radio-frequency input terminals 111 and 112 are external connection terminals included in the radio-frequency circuit 1 and are designed to receive radio-frequency transmit signals from the RFIC3. Each of the antenna connection terminals 101 and 102, the radio-frequency input terminals 111 and 112, and the terminals included in the switches 31 to 33, which will be described later, may be a metal conductor such as a metal electrode or metal bump or may be a point (node) in a metal wire line.

The power amplifier 10 is an example of a first power amplifier. The input end of the power amplifier 10 is coupled to the radio-frequency input terminal 111, and the output end of the power amplifier 10 is coupled to a common terminal 31a of the switch 31. The power amplifier 10 is capable of amplifying signals in a band A and a band B.

The power amplifier 20 is an example of a second power amplifier. The input end of the power amplifier 20 is coupled to the radio-frequency input terminal 112, and the output end of the power amplifier 20 is coupled to a terminal 32c of the switch 32. The power amplifier 20 is capable of amplifying signals in the band B.

Each of the power amplifiers 10 and 20 has an amplifier transistor. The amplifier transistor is, for example, a bipolar transistor, such as a heterojunction bipolar transistor (HBT), or a field-effect transistor, such as a metal-oxide-semiconductor field-effect transistor (MOSFET).

The power amplifier 10 may be capable of outputting a first maximum transmit power, and the power amplifier 20 may be capable of outputting a second maximum transmit power that is higher than the first maximum transmit power. More specifically, the power amplifier 10 is capable of outputting transmit signals in a first power class, and the power amplifier 20 is capable of outputting transmit signals in a second power class that has a maximum output power higher than the maximum output power of the first power class.

The power amplifier 20 can handle higher power than the power amplifier 10. However, because large current flows through the power amplifier 20, the circuit size increases and the power efficiency can degrade due to the need for a low-impedance output matching circuit. Considering this, the power amplifier 10 can be used without using the power amplifier 20 to exclusively transmit band-A or band-B signals, which improves the power efficiency of the radio-frequency circuit 1.

Power classes refer to classification divisions of user equipment (UE) output power, defined by, for example, maximum output power. As the power class number increases, the allowable output power increases. For example, in 3GPP (registered trademark), the allowable maximum output power for Power Class 1 is 31 dBm, the allowable maximum output power for Power Class 1.5 is 29 dBm, the allowable maximum output power for Power Class 2 is 26 dBm, and the allowable maximum output power for Power Class 3 is 23 dBm.

The maximum output power of a UE is defined based on the output power at the antenna end of the UE. The maximum output power of a UE can be measured using a method defined by, for example, 3GPP (registered trademark) or other standardization organizations. For example, in FIG. 1, the maximum output power can be measured by measuring the power emitted from the antenna 2A or 2B. In place of measuring emitted power, the output power of the antenna 2A or 2B can be measured using a measuring device (for example, a spectrum analyzer) that is coupled to a terminal provided near the antenna 2A or 2B.

The filter 41 is an example of a first filter. The filter 41 is a transmit filter having a pass band that includes the band A. The input end of the filter 41 is coupled to a terminal 31b of the switch 31, and the output end of the filter 41 is coupleable to the antenna connection terminal 101 or 102 via the switch 33.

The filter 42 is a receive filter having a pass band that includes the band A. The input end of the filter 42 is coupleable to the antenna connection terminal 101 or 102 via the switch 33, and the output end of the filter 42 is coupled to a low-noise amplifier (not illustrated).

The filter 43 is an example of a second filter. The filter 43 is a transmit filter having a pass band that includes the band B, which differs from the band A. The input end of the filter 43 is coupled to a common terminal 32a of the switch 32, and the output end of the filter 43 is coupleable to the antenna connection terminal 101 or 102 via the switch 33.

The filter 44 is a receive filter having a pass band that includes the band B. The input end of the filter 44 is coupleable to the antenna connection terminal 101 or 102 via the switch 33, and the output end of the filter 44 is coupled to a low-noise amplifier (not illustrated).

The filters 41 and 42 constitute a duplexer designed to transmit and receive band-A signals. The filters 43 and 44 constitute a duplexer designed to transmit and receive band-B signals. The radio-frequency circuit 1 according to the present embodiment does not necessarily include the filters 42 and 44.

The switch 31 is an example of a first switch. The switch 31 is coupled between the power amplifier 10 and the filters 41 and 43. The switch 31 is operable to alternate between coupling the power amplifier 10 to the filter 41 and coupling the power amplifier 10 to the filter 43.

The switch 32 is an example of a second switch. The switch 32 is coupled between the switch 31 and the power amplifier 20, and the filter 43. The switch 32 is operable to alternate between coupling the power amplifier 10 to the filter 43 and coupling the power amplifier 20 to the filter 43.

More specifically, the switch 31 has the common terminal 31a (a first common terminal), the terminal 31b (a first terminal), and the terminal 31c (a second terminal). The switch 32 has the common terminal 32a (a second common terminal), the terminal 32b (a third terminal), and the terminal 32c (a fourth terminal). The common terminal 31a is coupled to the output end of the power amplifier 10. The terminal 31b is coupled to the input end of the filter 41. The terminal 31c is coupled to the terminal 32b. The terminal 32c is coupled to the output end of the power amplifier 20. The common terminal 32a is coupled to the input end of the filter 43.

The switch 33 is an example of a fourth switch. The switch 33 is coupled between the filters 41 to 44 and the antenna connection terminals 101 and 102. The switch 33 is operable to couple the filter 41 to the antenna connection terminal 101 or 102 and to couple the filter 43 to the antenna connection terminal 101 or 102. By using the switch 33, the antenna 2A or 2B can be selected to transmit or receive band-A signals or to transmit or receive band-B signals, depending on conditions such as antenna sensitivity and other factors.

More specifically, the switch 33 has terminals 33a, 33b, 33c, and 33d. The switch 33 is operable to couple the terminal 33a to the terminal 33c or 33d and to couple the terminal 33b to the terminal 33c or 33d. The terminal 33a is coupled to the antenna connection terminal 101. The terminal 33b is coupled to the antenna connection terminal 102. The terminal 33c is coupled to the output end of the filter 41 and the input end of the filter 42. The terminal 33d is coupled to the output end of the filter 43 and the input end of the filter 44.

The radio-frequency circuit 1 according to the present embodiment does not necessarily include the switch 33. The output end of the filter 41 and the input end of the filter 42 may be directly coupled to the antenna connection terminal 101, and the output end of the filter 43 and the input end of the filter 44 may be directly coupled to the antenna connection terminal 102. In this case, band-A signals can be transmitted and received by the antenna 2A, and band-B signals can be transmitted and received by the antenna 2B.

In the present embodiment, each of the band A and the band B is, for example, 4G-LTE Band B8, 5G-NR Band n8 (transmit frequency range: 880-915 MHZ, receive frequency range 925-960 MHZ), 4G-LTE Band B20, 5G-NR Band n20 (transmit frequency range: 832-862 MHz, receive frequency range 791-821 MHz), 4G-LTE Band B26, 5G-NR Band n26 (transmit frequency range: 814-849 MHZ, receive frequency range 859-894 MHZ), 4G-LTE Band B28, or 5G-NR Band n28 (transmit frequency range: 703-748 MHZ, receive frequency range 758-803 MHZ).

### [1.3 Circuit States in Different Transfer Modes]

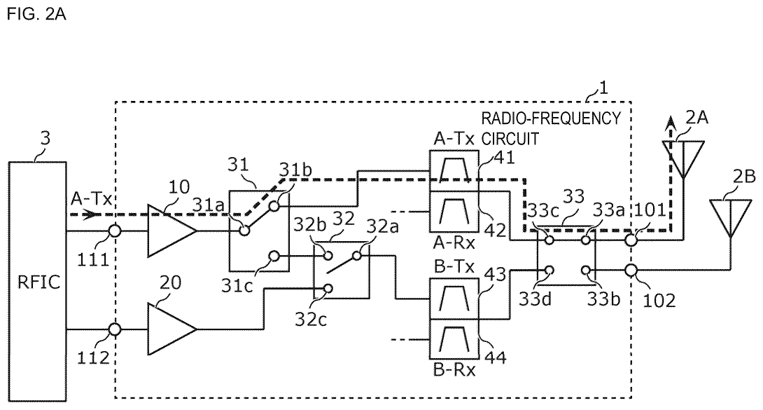

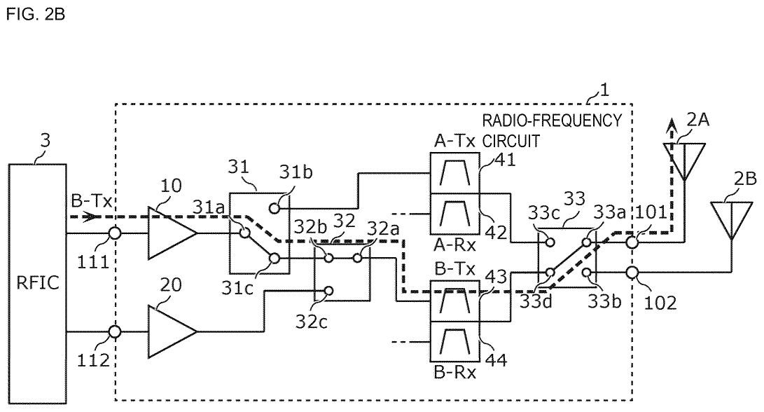

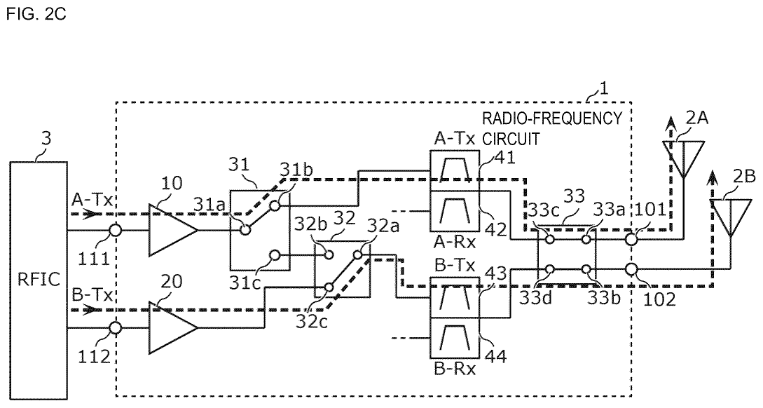

FIG. 2A illustrates the circuit state of the radio-frequency circuit 1 according to the embodiment assuming band-A signals are exclusively transmitted. FIG. 2A illustrates the signal flow assuming signals in the band A out of the band A and the band B are exclusively transmitted (hereinafter referred to as mode A).

As illustrated in FIG. 2A, assuming mode A is activated, the common terminal 31a is connected to the terminal 31b, the common terminal 31a is disconnected from the terminal 31c, and the terminal 33a is connected to the terminal 33c.

In this state, band-A transmit signals are transferred through the transmit path that includes the radio-frequency input terminal 111, the power amplifier 10, the switch 31, the filter 41, the switch 33, the antenna connection terminal 101, and the antenna 2A. In mode A, under certain conditions such as antenna sensitivity and other factors, the terminals 33b and 33c may be connected, allowing band-A transmit signals to be output from the antenna 2B.

FIG. 2B illustrates the circuit state of the radio-frequency circuit 1 according to the embodiment assuming band-B signals are exclusively transmitted. FIG. 2B illustrates the signal flow assuming signals in the band B out of the band A and the band B are exclusively transmitted (hereinafter referred to as mode B).

As illustrated in FIG. 2B, assuming mode B is activated, the common terminal 31a is connected to the terminal 31c, the common terminal 31a is disconnected from the terminal 31b, the common terminal 32a is connected to the terminal 32b, and the terminal 33a is connected to the terminal 33d.

In this state, band-B transmit signals are transferred through the transmit path that includes the radio-frequency input terminal 111, the power amplifier 10, the switch 31, the switch 32, the filter 43, the switch 33, the antenna connection terminal 101, and the antenna 2A. In mode B, under certain conditions such as antenna sensitivity and other factors, the terminals 33b and 33d may be connected, allowing band-B transmit signals to be output from the antenna 2B.

FIG. 2C illustrates the circuit state of the radio-frequency circuit 1 according to the embodiment assuming band-A signals and band-B signals are simultaneously transmitted. FIG. 2C illustrates the signal flow assuming signals in the band A and the band B are simultaneously transmitted (hereinafter referred to as mode C).

As illustrated in FIG. 2C, assuming mode C is activated, the common terminal 31a is connected to the terminal 31b, the common terminal 31a is disconnected from the terminal 31c, the common terminal 32a is connected to the terminal 32c, the terminal 33a is connected to the terminal 33c, and the terminal 33b is connected to the terminal 33d.

In this state, band-A transmit signals are transferred through the transmit path that includes the radio-frequency input terminal 111, the power amplifier 10, the switch 31, the filter 41, the switch 33, the antenna connection terminal 101, and the antenna 2A. Band-B transmit signals are transferred through the transmit path that includes the radio-frequency input terminal 112, the power amplifier 20, the switch 32, the filter 43, the switch 33, the antenna connection terminal 102, and the antenna 2B. In mode C, under certain conditions such as antenna sensitivity and other factors, the terminals 33b and 33c may be connected, allowing band-A transmit signals to be output from the antenna 2B, while the terminals 33a and 33d may be connected, allowing band-B transmit signals to be output from the antenna 2A.

The connection configurations of the radio-frequency circuit 1 illustrated in FIGS. 2A to 2C enable the following operations: by coupling the power amplifier 10 and the filter 41 through control of the switch 31, band-A signals can be exclusively transmitted using the signal path that includes the power amplifier 10 and the filter 41; by coupling the power amplifier 10 to the filter 43 through control of the switches 31 and 32, band-B signals can be exclusively transmitted using the signal path that includes the power amplifier 10 and the filter 43; by coupling the power amplifier 10 to the filter 41 and coupling the power amplifier 20 to the filter 43 through control of the switches 31 and 32, band-A signals can be transmitted using the signal path that includes the power amplifier 10 and the filter 41, and at the same time, band-B signals can be transmitted using the signal path that includes the power amplifier 20 and the filter 43.

Next, a radio-frequency circuit 501 according to a comparative example with a known configuration will be described for reference.

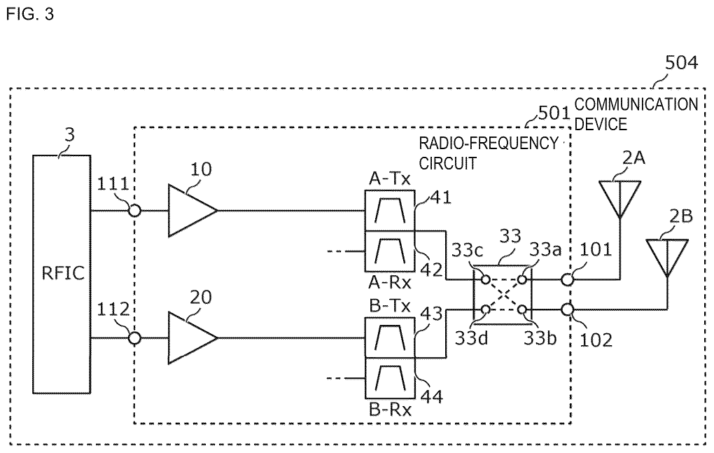

FIG. 3 is a circuit configuration diagram of a radio-frequency circuit 501 and a communication device 504 according to a comparative example. The radio-frequency circuit 501 illustrated in the drawing includes power amplifiers 10 and 20, filters 41, 42, 43, and 44, a switch 33, antenna connection terminals 101 and 102, and radio-frequency input terminals 111 and 112. The radio-frequency circuit 501 according to the comparative example differs from the radio-frequency circuit 1 according to the embodiment in that the switches 31 and 32 are not provided. The following describes the radio-frequency circuit 501 according to the comparative example with a main focus on configurational features different from the radio-frequency circuit 1 according to the embodiment, and descriptions of the same configurational features as the radio-frequency circuit 1 will not be repeated.

The input end of the filter 41 is coupled to the output end of the power amplifier 10, and the output end of the filter 41 is coupleable to the antenna connection terminals 101 or 102 via the switch 33. The input end of the filter 43 is coupled to the output end of the power amplifier 20, and the output end of the filter 43 is coupleable to the antenna connection terminals 101 or 102 via the switch 33.

Assuming signals in the band A out of the band A and the band B are exclusively transmitted (mode A), terminals 33a and 33c are connected in the radio-frequency circuit 501 according to the comparative example. In this state, band-A transmit signals are transferred through the transmit path that includes the radio-frequency input terminal 111, the power amplifier 10, the filter 41, the switch 33, the antenna connection terminal 101, and the antenna 2A. In mode A, terminals 33b and 33c may be connected, allowing band-A transmit signals to be output from the antenna 2B.

Assuming signals in the band B out of the band A and the band B are exclusively transmitted (mode B), terminals 33b and 33d are connected in the radio-frequency circuit 501 according to the comparative example. In this state, band-B transmit signals are transferred through the transmit path that includes the radio-frequency input terminal 112, the power amplifier 20, the filter 43, the switch 33, the antenna connection terminal 102, and the antenna 2B. In mode B, the terminals 33a and 33d may be connected, allowing band-B transmit signals to be output from the antenna 2A.

Assuming signals in the band A and signals in the band B are simultaneously transmitted (mode C), the terminals 33a and 33c are connected and the terminals 33b and 33d are connected in the radio-frequency circuit 501 according to the comparative example. In this state, band-A transmit signals can be transferred through the transmit path that includes the radio-frequency input terminal 111, the power amplifier 10, the filter 41, the switch 33, the antenna connection terminal 101, and the antenna 2A, and at the same time, band-B transmit signals can be transferred through the transmit path that includes the radio-frequency input terminal 112, the power amplifier 20, the filter 43, the switch 33, the antenna connection terminal 102, and the antenna 2B. In mode C, the terminals 33b and 33c may be connected, allowing band-A transmit signals to be output from the antenna 2B, while the terminals 33a and 33d may be connected, allowing band-B transmit signals to be output from the antenna 2A.

The connection configurations of the radio-frequency circuit 501 according to the comparative example enable the following operations: band-A signals can be exclusively transmitted using the signal path that includes the power amplifier 10 and the filter 41; band-B signals can be exclusively transmitted using the signal path that includes the power amplifier 20 and the filter 43; band-A signals can be transmitted using the signal path that includes the power amplifier 10 and the filter 41, and at the same time, band-B signals can be transmitted using the signal path that includes the power amplifier 20 and the filter 43.

In this case, different power amplifiers, specifically the power amplifiers 10 and 20, are used respectively assuming band-A signals are exclusively transmitted and assuming band-B signals are exclusively transmitted. Thus, it is expected that the power efficiency of the radio-frequency circuit 501 can vary between assuming band-A signals are exclusively transmitted and assuming band-B signals are exclusively transmitted.

By contrast, the radio-frequency circuit 1 according to the present embodiment uses a single power amplifier for both exclusively transmitting band-A signals and exclusively transmitting band-B signals, aiming to avoid incorporating additional large-size power amplifiers. The power amplifier 20 has a higher maximum transmit power than the power amplifier 10. However, because a high maximum transmit power is not required to exclusively transmit band-B signals, the power amplifier 10 is used to exclusively transmit band-B signals. This configuration optimizes the power efficiency of the radio-frequency circuit 1.

More specifically, assuming signals in the band A out of the band A and the band B are exclusively transmitted, the power amplifier 10 and the filter 41 are coupled through control of the switch 31. Assuming signals in the band B out of the band A and the band B are exclusively transmitted, the power amplifier 10 and the filter 43 are coupled through control of the switches 31 and 32. Assuming signals in the band A and signals in the band B are simultaneously transmitted, the power amplifier 10 and the filter 41 are coupled and the power amplifier 20 and the filter 43 are coupled through control of the switches 31 and 32.

As described above, because the same power amplifier 10 is used for both exclusively transmitting band-A signals and exclusively transmitting band-B signals, the power efficiency assuming exclusively transmitting band-A signals and the power efficiency assuming exclusively transmitting band-B signals can be optimized in the same manner. As such, the power efficiency assuming amplifying radio-frequency signals in different frequency bands can be optimized.

### [1.4 Circuit Configuration of Radio-Frequency Circuit 1A According to Modification]

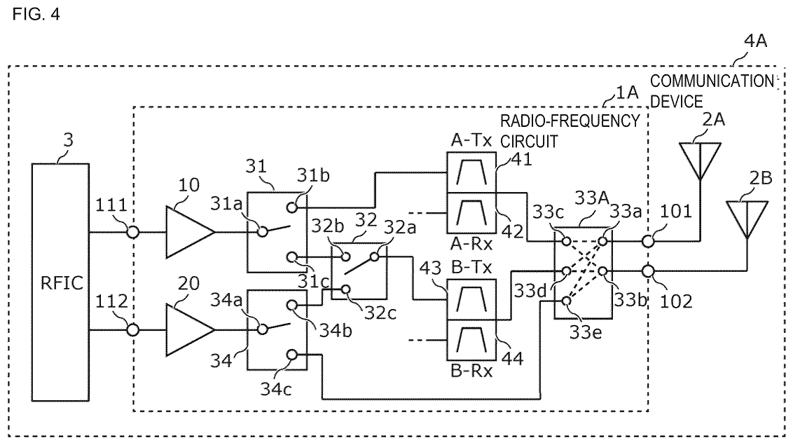

FIG. 4 is a circuit configuration diagram of a radio-frequency circuit 1A and a communication device 4A according to a modification. As illustrated in the drawing, the communication device 4A includes the radio-frequency circuit 1A, antennas 2A and 2B, and an RFIC 3. The communication device 4A according to the present modification differs from the communication device 4 according to the embodiment in the circuit configuration of the radio-frequency circuit 1A. The following describes a circuit configuration of the radio-frequency circuit 1A according to the present modification.

The radio-frequency circuit 1A includes power amplifiers 10 and 20, filters 41, 42, 43, and 44, switches 31, 32, 33A, and 34, antenna connection terminals 101 and 102, and radio-frequency input terminals 111 and 112. The radio-frequency circuit 1A according to the present modification differs from the radio-frequency circuit 1 according to the embodiment in the additional incorporation of the switch 34 and the configuration of the switch 33A. The following describes the radio-frequency circuit 1A according to the present modification with a main focus on configurational features different from the radio-frequency circuit 1 according to the embodiment, and descriptions of the same configurational features as the radio-frequency circuit 1 will not be repeated.

The power amplifier 10 is an example of a first power amplifier. The input end of the power amplifier 10 is coupled to the radio-frequency input terminal 111, and the output end of the power amplifier 10 is coupled to a common terminal 31a. The power amplifier 10 is capable of amplifying signals in a band A and a band B for 4G-LTE or 5G-NR.

The power amplifier 20 is an example of a second power amplifier. The input end of the power amplifier 20 is coupled to the radio-frequency input terminal 112, and the output end of the power amplifier 20 is coupled to a common terminal 34a of the switch 34. The power amplifier 20 is capable of amplifying signals in the band B for 4G-LTE or 5G-NR, as well as 2G signals.

The power amplifier 10 is capable of outputting a first maximum transmit power, and the power amplifier 20 is capable of outputting a second maximum transmit power that is higher than the first maximum transmit power. More specifically, the power amplifier 10 is capable of outputting transmit signals in a first power class, and the power amplifier 20 is capable of outputting transmit signals in a second power class that has a maximum output power higher than the maximum output power of the first power class. The maximum output power of 2G signals is greater than the maximum output power of 4G-LTE signals and the maximum output power of 5G-NR signals.

The power amplifier 20 can handle higher power than the power amplifier 10. However, because large current flows through the power amplifier 20, the circuit size increases and the power efficiency can degrade due to the need for a low-impedance output matching circuit.

The filter 41 is an example of a first filter. The filter 41 is a transmit filter having a pass band that includes the band A. The input end of the filter 41 is coupled to a terminal 31b, and the output end of the filter 41 is coupleable to the antenna connection terminal 101 or 102 via the switch 33A.

The filter 43 is an example of a second filter. The filter 43 is a transmit filter having a pass band that includes the band B. The input end of the filter 43 is coupled to a common terminal 32a, and the output end of the filter 43 is coupleable to the antenna connection terminal 101 or 102 via the switch 33A.

The switch 31 is an example of a first switch. The switch 31 is coupled between the power amplifier 10 and the filters 41 and 43. The switch 31 is operable to alternate between coupling the power amplifier 10 to the filter 41 and coupling the power amplifier 10 to the filter 43.

The switch 32 is an example of a second switch. The switch 32 is coupled between the switches 31 and 34 and the filter 43. The switch 32 is operable to alternate between coupling the power amplifier 10 to the filter 43 and coupling the power amplifier 20 to the filter 43.

The switch 34 is an example of a third switch. The switch 34 is coupled between the power amplifier 20, and the switch 32 and the antenna connection terminals 101 and 102. The switch 34 is operable to alternate between coupling the power amplifier 20 to the filter 43 and coupling the power amplifier 20 to the antenna connection terminal 101 or 102 without involving the switch 32 and the filter 43.

More specifically, the switch 34 has the common terminal 34a (a third common terminal), a terminal 34b (a fifth terminal), and a terminal 34c (a sixth terminal). The common terminal 34a is coupled to the output end of the power amplifier 20. The terminal 34b is coupled to the terminal 32c. The terminal 34c is coupleable to the antenna connection terminal 101 or 102 via the switch 33a.

The switch 33A is an example of a fourth switch. The switch 33A is coupled between the antenna connection terminals 101 and 102, and the filters 41 and 43 and the switch 34. The switch 33A is operable to couple the antenna connection terminal 101 to any one of the filters 41, 43, and the switch 34 and to couple the antenna connection terminal 102 to any one of the filters 41, 43, and the switch 34.

More specifically, the switch 33A has terminals 33a, 33b, 33c, 33d, and 33e. The terminal 33a is coupled to the antenna connection terminal 101. The terminal 33b is coupled to the antenna connection terminal 102. The terminal 33c is coupled to the output end of the filter 41 and the input end of the filter 42. The terminal 33d is coupled to the output end of the filter 43 and the input end of the filter 44. The terminal 33e is directly coupled to the terminal 34c. By using the switch 33A, the antenna 2A or 2B can be selected to transmit or receive band-A signals, to transmit or receive band-B signals, or to transmit 2G signals, depending on conditions such as antenna sensitivity and other factors.

### [1.5 Circuit States in Different Transfer Modes in Radio-Frequency Circuit 1A According to Modification]

The radio-frequency circuit 1A according to the modification enables (1) exclusive transmission of band-A signal (mode A), (2) exclusive transmission of band-B signal (mode B), (3) simultaneous transmission of band-A signal and band-B signal (mode C), and (4) transmission of 2G signal (mode D).

Assuming mode A is activated, the common terminal 31a is connected to the terminal 31b, the common terminal 31a is disconnected from the terminal 31c, and the terminal 33a is connected to the terminal 33c.

In this state, band-A transmit signals are transferred through the transmit path that includes the radio-frequency input terminal 111, the power amplifier 10, the switch 31, the filter 41, the switch 33A, the antenna connection terminal 101, and the antenna 2A. In mode A, under certain conditions such as antenna sensitivity and other factors, the terminals 33b and 33c may be connected, allowing band-A transmit signals to be output from the antenna 2B.

Assuming mode B is activated, the common terminal 31a is connected to the terminal 31c, the common terminal 31a is disconnected from the terminal 31b, the common terminal 32a is connected to the terminal 32b, and the terminal 33a is connected to the terminal 33d.

In this state, band-B transmit signals are transferred through the transmit path that includes the radio-frequency input terminal 111, the power amplifier 10, the switch 31, the switch 32, the filter 43, the switch 33A, the antenna connection terminal 101, and the antenna 2A. In mode B, under certain conditions such as antenna sensitivity and other factors, the terminals 33b and 33d may be connected, allowing band-B transmit signals to be output from the antenna 2B.

Assuming mode C is activated, the common terminal 31a is connected to the terminal 31b, the common terminal 31a is disconnected from the terminal 31c, the common terminal 34a is connected to the terminal 34b, the common terminal 34a is disconnected from the terminal 34c, the common terminal 32a is connected to the terminal 32c, the terminal 33a is connected to the terminal 33c, and the terminal 33b is connected to the terminal 33d.

In this state, band-A transmit signals are transferred through the transmit path that includes the radio-frequency input terminal 111, the power amplifier 10, the switch 31, the filter 41, the switch 33A, the antenna connection terminal 101, and the antenna 2A. Band-B transmit signals are transferred through the transmit path that includes the radio-frequency input terminal 112, the power amplifier 20, the switch 34, the switch 32, the filter 43, the switch 33A, the antenna connection terminal 102, and the antenna 2B. In mode C, under certain conditions such as antenna sensitivity and other factors, the terminals 33b and 33c may be connected, allowing band-A transmit signals to be output from the antenna 2B, while the terminals 33a and 33d may be connected, allowing band-B transmit signals to be output from the antenna 2A.

In the connection configurations of the radio-frequency circuit 1A, assuming signals in the band A out of the band A and the band B are exclusively transmitted, the power amplifier 10 and the filter 41 are coupled through control of the switch 31. Assuming signals in the band B out of the band A and the band B are exclusively transmitted, the power amplifier 10 and the filter 43 are coupled through control of the switches 31 and 32. Assuming signals in the band A and signals in the band B are simultaneously transmitted, the power amplifier 10 and the filter 41 are coupled and the power amplifier 20 and the filter 43 are coupled through control of the switches 31, 32, and 34. As described above, because the same power amplifier 10 is used for both exclusively transmitting band-A signals and exclusively transmitting band-B signals, the power efficiency assuming exclusively transmitting band-A signals and the power efficiency assuming exclusively transmitting band-B signals can be optimized in the same manner.

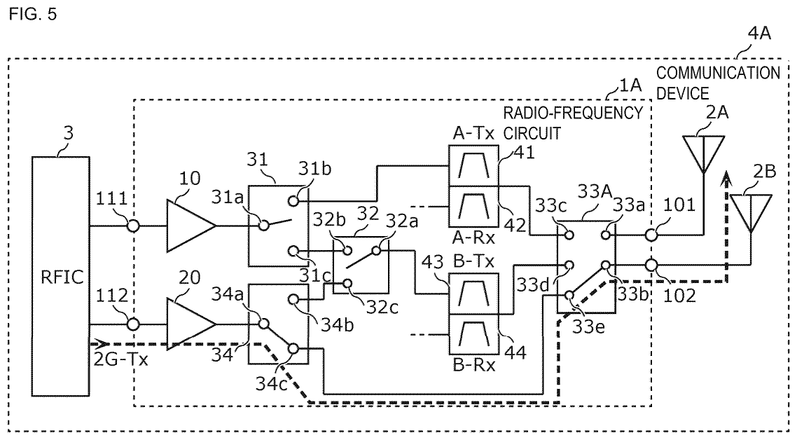

Next, the case in which mode D is activated will be described with reference to FIG. 5. FIG. 5 illustrates the circuit state of the radio-frequency circuit 1A according to the modification assuming 2G signals are transmitted.

As illustrated in FIG. 5, assuming mode D is activated, the common terminal 34a is connected to the terminal 34c, the common terminal 34a is disconnected from the terminal 34b, and the terminal 33b is connected to the terminal 33e.

In this state, 2G transmit signals are transferred through the transmit path that includes the radio-frequency input terminal 112, the power amplifier 20, the switch 34, the switch 33A, the antenna connection terminal 102, and the antenna 2B. In mode D, under certain conditions such as antenna sensitivity and other factors, the terminals 33a and 33e may be connected, allowing 2G transmit signals to be output from the antenna 2A.

With the connection configuration of the radio-frequency circuit 1A illustrated in FIG. 5, by coupling the power amplifier 20 and the antenna connection terminal 101 or 102 via the switch 34 without involving the switch 32 and the filter 43, 2G signals can be transmitted using the signal path that includes the power amplifier 20 and the antenna connection terminal 101 or 102.

As described, because the power amplifier 20 is used to amplify 2G signals, which require higher-power transmission compared to 4G and 5G signals, the power amplifier 10 does not need to support high-power operation. The power efficiency of the power amplifier 10, which is used for exclusive transmission of 4G or 5G band-A signals and for exclusive transmission of 4G or 5G band-B signals, can thus be optimized rather than reduced. Furthermore, because high-power 2G transmit signals can be transferred without involving the switch 32 and the filter 43, 2G signals can be transmitted with low loss.

### 2 Effects

As described above, the radio-frequency circuit 1 according to the present embodiment includes the power amplifier 10 configured to output the first maximum transmit power, the power amplifier 20 configured to output the second maximum transmit power that is higher than the first maximum transmit power, the filter 41 having a pass band that includes the band A, the filter 43 having a pass band that includes the band B different from the band A, the switch 31 coupled between the power amplifier 10 and the filter 41 and between the power amplifier 10 and the filter 43, and the switch 32 coupled between the switch 31 and the filter 43 and between the power amplifier 20 and the filter 43.

With this configuration, assuming signals in the band A are exclusively transmitted, the power amplifier 10 and the filter 41 can be coupled through control of the switch 31. Assuming signals in the band B are exclusively transmitted, the power amplifier 10 and the filter 43 can be coupled through control of the switches 31 and 32. Assuming signals in the band A and signals in the band B are simultaneously transmitted, the power amplifier 10 and the filter 41 can be coupled and the power amplifier 20 and the filter 43 can be coupled through control of the switches 31 and 32. As described above, because the same power amplifier 10 is used for both exclusively transmitting band-A signals and exclusively transmitting band-B signals, the power efficiency assuming exclusively transmitting band-A signals and the power efficiency assuming exclusively transmitting band-B signals can be optimized in the same manner. As such, the power efficiency assuming amplifying radio-frequency signals in different frequency bands can be optimized.

The power amplifier 20 can handle higher power than the power amplifier 10. However, the circuit size can increase and the power efficiency can degrade. Considering this, the power amplifier 10 is used without using the power amplifier 20 to exclusively transmit band-A or band-B signals, which improves the power efficiency of the radio-frequency circuit 1.

In an example, in the radio-frequency circuit 1, the switches 31 and 32 may be configured to alternate between coupling the power amplifier 10 to the filter 41 and coupling the power amplifier 10 to the filter 43 in a configuration in which the power amplifier 10 operates, and the switches 31 and 32 may be configured to couple the power amplifier 10 to the filter 41 and to couple the power amplifier 20 to the filter 43 in a configuration in which the power amplifiers 10 and 20 simultaneously operate.

These configurations enable switching among exclusive transmission of band-A signal, exclusive transmission of band-B signal, and simultaneous transmission of band-A and band-B signals.

In an example, in the radio-frequency circuit 1, the switch 31 may have the common terminal 31a and the terminals 31b and 31c, and the switch 32 may have the common terminal 32a and the terminals 32b and 32c. The common terminal 31a may be coupled to the output end of the power amplifier 10. The terminal 31b may be coupled to the input end of the filter 41. The terminal 31c may be coupled to the terminal 32b. The terminal 32c may be coupled to the output end of the power amplifier 20. The common terminal 32a may be coupled to the input end of the filter 43.

In an example, in the radio-frequency circuit 1, the switches 31 and 32 may be configured to alternate between coupling the common terminal 31a to the terminal 31b, and coupling the common terminal 31a to the terminal 31c while coupling the common terminal 32a to the terminal 32b, in a configuration in which the power amplifier 10 operates, the switches 31 and 32 may be configured to couple the common terminal 31a to the terminal 31b and couple the common terminal 32a to the terminal 32c in a configuration in which the power amplifiers 10 and 20 simultaneously operate.

These configurations enable switching among exclusive transmission of band-A signal, exclusive transmission of band-B signal, and simultaneous transmission of band-A and band-B signals based on switch configurations, thereby simplifying the radio-frequency circuit 1.

In an example, in radio-frequency circuit 1, the power amplifier 10 may be configured to amplify signals in the band A and the band B, and the power amplifier 20 may be configured to amplify signals in the band B.

In an example, the radio-frequency circuit 1A according to the modification may include the power amplifiers 10 and 20, the filter 41 having a pass band that includes the band A, the filter 43 having a pass band that includes the band B, the switch 31 coupled between the power amplifier 10 and the filters 41 and 43, configured to alternate between coupling the power amplifier 10 to the filter 41 and coupling the power amplifier 10 to the filter 43, the switch 32 coupled between the switch 31 and the power amplifier 20, and the filter 43, configured to alternate between coupling the power amplifier 10 to the filter 43 and coupling the power amplifier 20 to the filter 43, the antenna connection terminal 101 coupled to one of the filters 41 and 43, the antenna connection terminal 102 coupled to the other of the filters 41 and 43, and the switch 34 coupled between the power amplifier 20, and the switch 32 and the antenna connection terminals 101 and 102, configured to alternate between coupling the power amplifier 20 to the filter 43 and coupling the power amplifier 20 to the antenna connection terminal 101 or 102.

In an example, the radio-frequency circuit 1A may be configured such that the power amplifier 20 is coupled to the antenna connection terminal 101 or 102 without involving the switch 32 and the filter 43.

With this configuration, assuming the power amplifier 20 is used to amplify 2G signals, which require higher-power transmission compared to 4G and 5G signals, the power amplifier 10 does not need to support high-power operation. The power efficiency of the power amplifier 10, which is used for exclusive transmission of 4G or 5G band-A signals and for exclusive transmission of 4G or 5G band-B signals, can thus be optimized rather than reduced. Furthermore, because high-power 2G transmit signals can be transferred without involving the switch 32 and the filter 43, 2G signals can be transmitted with low loss.

In an example, in the radio-frequency circuit 1A, the power amplifier 10 may be configured to amplify 4G-LTE signals and 5G-NR signals, and the power amplifier 20 may be configured to amplify 2G signals, 4G-LTE signals, and 5G-NR signals.

In an example, in the radio-frequency circuit 1A, the switch 34 may have the common terminal 34a and the terminals 34b and 34c. The common terminal 34a may be coupled to the output end of the power amplifier 20, the terminal 34b may be coupled to the switch 32, and the terminal 34c may be coupled to the antenna connection terminal 101 or 102.

In an example, in the radio-frequency circuit 1A, the switch 34 may be configured such that the common terminal 34a and the terminal 34c are coupled.

With this configuration, switching between transmitting 2G signals and transmitting 4G or 5G signals can be achieved based om switch configurations, thereby simplifying the radio-frequency circuit 1A.

In an example, the radio-frequency circuit 1A may further include the switch 33A coupled between the antenna connection terminals 101 and 102, and the filters 41 and 43 and the switch 34, configured to couple the antenna connection terminal 101 to any one of the filters 41, 43, and the switch 34 and to couple the antenna connection terminal 102 to any one of the filters 41, 43, and the switch 34.

With this configuration, the antenna 2A or 2B can be selected to transmit or receive band-A signals, to transmit or receive band-B signals, or to transmit 2G signals, depending on conditions such as antenna sensitivity and other factors.

In an example, in the radio-frequency circuits 1 and 1A, each of the band A and the band B may be 4G-LTE Band B8, 5G-NR Band n8, 4G-LTE Band B20, 5G-NR Band n20, 4G-LTE Band B26, 5G-NR Band n26, 4G-LTE Band B28, or 5G-NR Band n28.

The communication device 4 according to the present embodiment includes the RFIC 3 configured to process radio-frequency signals and the radio-frequency circuit 1 configured to transfer radio-frequency signals between the RFIC 3 and the antennas 2A and 2B.

This configuration enables the communication device 4 to achieve the same effects as the radio-frequency circuit 1.

### Other Embodiments

The radio-frequency circuit and the communication device according to the present disclosure have been described by using the embodiment and modification, but the radio-frequency circuit and the communication device according to the present disclosure are not limited to the embodiment and modification. The present disclosure also embraces other embodiments implemented as any combination of the constituent elements of the embodiment and modification, other modifications obtained by making various modifications to the embodiment that occur to those skilled in the art without departing from the scope of the present disclosure, and various hardware devices including the radio-frequency circuit or communication device according to the present disclosure.

For example, in the circuit configurations of the radio-frequency circuit and communication device according to the embodiment and modification described above, other circuit elements and wire lines may be inserted in the paths connecting the circuit elements and signal paths that are illustrated in the drawings.

5G-NR or 4G-LTE bands are used in the embodiment and modification described above. However, other communication bands for different radio access technologies may be used in addition to or instead of 5G-NR or 4G-LTE. For example, communication bands for wireless local area networks may be used. For example, millimeter-wave bands at 7 gigahertz or higher may be used. In this case, the radio-frequency circuit 1, the antennas 2A and 2B, and the RFIC 3 form a millimeter-wave antenna circuit, and, for example, distributed constant filter may be used as filters.

The following describes the features of the amplifier circuit and the communication device explained based on the embodiment.

<1>

A radio-frequency circuit comprising:
a first power amplifier and a second power amplifier;
a first filter having a pass band that includes a first band;
a second filter having a pass band that includes a second band;
a first switch coupled between the first power amplifier, and the first filter and the second filter; and
a second switch coupled between the first switch and the second power amplifier, and the second filter.
   <2>

The radio-frequency circuit according to <1>, wherein
the first switch and the second switch are configured to
alternate among (1) coupling the first power amplifier to the first filter, (2) coupling the first power amplifier to the second filter, and (3) coupling the first power amplifier to the first filter and coupling the second power amplifier to the second filter.
   <3>

The radio-frequency circuit according to <1> or <2>, wherein
the first switch has a first common terminal, a first terminal, and a second terminal,
the second switch has a second common terminal, a third terminal, and a fourth terminal, and
the first common terminal is coupled to an output end of the first power amplifier, the first terminal is coupled to an input end of the first filter, the second terminal is coupled to the third terminal, the fourth terminal is coupled to an output end of the second power amplifier, and the second common terminal is coupled to an input end of the second filter.
   <4>

The radio-frequency circuit according to <3>, wherein
the first switch and the second switch are configured to
alternate among (1) coupling the first common terminal to the first terminal, (2) coupling the first common terminal to the second terminal while coupling the second common terminal to the third terminal, and (3) coupling the first common terminal to the first terminal and coupling the second common terminal to the fourth terminal.
   <5>

The radio-frequency circuit according to any of <1> to <4>, wherein
the first power amplifier is configured to amplify a signal in the first band and a signal in the second band, and
the second power amplifier is configured to amplify a signal in the second band.
   <6>

The radio-frequency circuit according to any of <1> to <5>, wherein
the first power amplifier is configured to output a first maximum transmit power, and
the second power amplifier is configured to output a second maximum transmit power that is higher than the first maximum transmit power.
   <7>

The radio-frequency circuit according to any of <1> to <6>, further comprising:
a first antenna connection terminal coupled to one of the first filter and the second filter;
a second antenna connection terminal coupled to another of the first filter and the second filter; and
a third switch coupled between the second power amplifier, and the second switch, the first antenna connection terminal, and the second antenna connection terminal, the third switch being configured to alternate between coupling the second power amplifier to the second filter and coupling the second power amplifier to the first antenna connection terminal or the second antenna connection terminal.
   <8>

The radio-frequency circuit according to <7>, configured such that
the second power amplifier is coupled to the first antenna connection terminal or the second antenna connection terminal without involving the second switch and the second filter.
   <9>

The radio-frequency circuit according to <7> or <8>, wherein
the first power amplifier is configured to amplify a 4G Long Term Evolution (LTE) signal and a 5th Generation (5G) New Radio (NR) signal, and
the second power amplifier is configured to amplify a 2G signal, a 4G-LTE signal, and a 5G-NR signal.
   <10>

The radio-frequency circuit according to any of <7> to <9>, wherein
the third switch has a third common terminal, a fifth terminal, and a sixth terminal, and
the third common terminal is coupled to an output end of the second power amplifier, the fifth terminal is coupled to the second switch, and the sixth terminal is coupled to the first antenna connection terminal or the second antenna connection terminal.
   <11>

The radio-frequency circuit according to <10>, wherein
the third switch is configured such that the third common terminal is coupled to the sixth terminal.
   <12>

The radio-frequency circuit according to any of <7> to <11>, further comprising:
a fourth switch coupled between the first antenna connection terminal and the second antenna connection terminal, and the first filter, the second filter, and the third switch, the fourth switch being configured to couple the first antenna connection terminal to any one of the first filter, the second filter, and the third switch, and to couple the second antenna connection terminal to any one of the first filter, the second filter, and the third switch.
   <13>

The radio-frequency circuit according to any of <1> to <12>, wherein
each of the first band and the second band is 4G-LTE Band B8, 5G-NR Band n8, 4G-LTE Band B20, 5G-NR Band n20, 4G-LTE Band B26, 5G-NR Band n26, 4G-LTE Band B28, or 5G-NR Band n28.
   <14>

A communication device comprising:
a signal processing circuit configured to process a radio-frequency signal; and
the radio-frequency circuit according to any of <1> to <13>, the radio-frequency circuit being configured to transfer the radio-frequency signal between the signal processing circuit and an antenna.

### INDUSTRIAL APPLICABILITY

The present disclosure can be used as a radio-frequency circuit provided at the front-end, in a wide variety of communication hardware, such as mobile phones.

### REFERENCE SIGNS LIST

1, 1A, 501 radio-frequency circuit
2A, 2B antenna
3 RF signal processing circuit (RFIC)
4, 4A, 504 communication device
10, 20 power amplifier
31, 32, 33, 33A, 34 switch
31a, 32a, 34a common terminal
31b, 31c, 32b, 32c, 33a, 33b, 33c, 33d, 33e, 34b, 34c terminal
41, 42, 43, 44 filter
101, 102 antenna connection terminal
111, 112 radio-frequency input terminal

1. A radio-frequency circuit comprising:
a first power amplifier configured to output a first maximum transmit power;
a second power amplifier configured to output a second maximum transmit power that is higher than the first maximum transmit power;
a first filter having a pass band that includes a first band;
a second filter having a pass band that includes a second band different from the first band;
a first switch coupled between the first power amplifier and the first filter and between the first power amplifier and the second filter; and
a second switch coupled between the first switch and the second filter and between the second power amplifier and the second filter.

2. The radio-frequency circuit according to claim 1, wherein
the first switch and the second switch are configured to
in a configuration in which the first power amplifier operates,
alternate between coupling the first power amplifier to the first filter and coupling the first power amplifier to the second filter, and
in a configuration in which the first power amplifier and the second power amplifier simultaneously operate,
couple the first power amplifier to the first filter and couple the second power amplifier to the second filter.

3. The radio-frequency circuit according to claim 2, wherein
the first switch has a first common terminal, a first terminal, and a second terminal,
the second switch has a second common terminal, a third terminal, and a fourth terminal, and
the first common terminal is coupled to an output end of the first power amplifier, the first terminal is coupled to an input end of the first filter, the second terminal is coupled to the third terminal, the fourth terminal is coupled to an output end of the second power amplifier, and the second common terminal is coupled to an input end of the second filter.

4. The radio-frequency circuit according to claim 3, wherein
the first switch and the second switch are configured to
in a configuration in which the first power amplifier operates,
alternate between coupling the first common terminal to the first terminal, and coupling the first common terminal to the second terminal while coupling the second common terminal to the third terminal, and
in a configuration in which the first power amplifier and the second power amplifier simultaneously operate, couple the first common terminal to the first terminal and couple the second common terminal to the fourth terminal.

5. The radio-frequency circuit according to claim 4, wherein
the first power amplifier is configured to amplify a signal in the first band and a signal in the second band, and
the second power amplifier is configured to amplify a signal in the second band.

6. The radio-frequency circuit according to claim 5, further comprising:
a first antenna connection terminal coupled to one of the first filter and the second filter;
a second antenna connection terminal coupled to another of the first filter and the second filter; and
a third switch coupled between the second power amplifier, and the second switch, the first antenna connection terminal, and the second antenna connection terminal, the third switch being configured to alternate between coupling the second power amplifier to the second filter and coupling the second power amplifier to the first antenna connection terminal or the second antenna connection terminal.

7. The radio-frequency circuit according to claim 6, configured such that
the second power amplifier is coupled to the first antenna connection terminal or the second antenna connection terminal without involving the second switch and the second filter.

8. The radio-frequency circuit according to claim 7, wherein
the first power amplifier is configured to amplify a 4G Long Term Evolution (LTE) signal and a 5th Generation (5G) New Radio (NR) signal, and
the second power amplifier is configured to amplify a 2G signal, a 4G-LTE signal, and a 5G-NR signal.

9. The radio-frequency circuit according to claim 8, wherein
the third switch has a third common terminal, a fifth terminal, and a sixth terminal, and
the third common terminal is coupled to an output end of the second power amplifier, the fifth terminal is coupled to the second switch, and the sixth terminal is coupled to the first antenna connection terminal or the second antenna connection terminal.

10. The radio-frequency circuit according to claim 9, wherein
the third switch is configured such that the third common terminal is coupled to the sixth terminal.

11. The radio-frequency circuit according to claim 10, further comprising:
a fourth switch coupled between the first antenna connection terminal and the second antenna connection terminal, and the first filter, the second filter, and the third switch, the fourth switch being configured to couple the first antenna connection terminal to any one of the first filter, the second filter, and the third switch, and to couple the second antenna connection terminal to any one of the first filter, the second filter, and the third switch.

12. The radio-frequency circuit according to claim 11, wherein
each of the first band and the second band is 4G-LTE Band B8, 5G-NR Band n8, 4G-LTE Band B20, 5G-NR Band n20, 4G-LTE Band B26, 5G-NR Band n26, 4G-LTE Band B28, or 5G-NR Band n28.

13. A communication device comprising:
a signal processing circuit configured to process a radio-frequency signal; and
the radio-frequency circuit according to claim 1, the radio-frequency circuit being configured to transfer the radio-frequency signal between the signal processing circuit and an antenna.

14. The radio-frequency circuit according to claim 1, wherein
the first switch has a first common terminal, a first terminal, and a second terminal,
the second switch has a second common terminal, a third terminal, and a fourth terminal, and
the first common terminal is coupled to an output end of the first power amplifier, the first terminal is coupled to an input end of the first filter, the second terminal is coupled to the third terminal, the fourth terminal is coupled to an output end of the second power amplifier, and the second common terminal is coupled to an input end of the second filter.

15. The radio-frequency circuit according to claim 14, wherein
the first switch and the second switch are configured to
in a configuration in which the first power amplifier operates,
alternate between coupling the first common terminal to the first terminal, and coupling the first common terminal to the second terminal while coupling the second common terminal to the third terminal, and
in a configuration in which the first power amplifier and the second power amplifier simultaneously operate, couple the first common terminal to the first terminal and couple the second common terminal to the fourth terminal.

16. The radio-frequency circuit according to claim 15, wherein
the first power amplifier is configured to amplify a signal in the first band and a signal in the second band, and
the second power amplifier is configured to amplify a signal in the second band.

17. The radio-frequency circuit according to claim 16, further comprising:
a first antenna connection terminal coupled to one of the first filter and the second filter;
a second antenna connection terminal coupled to another of the first filter and the second filter; and
a third switch coupled between the second power amplifier, and the second switch, the first antenna connection terminal, and the second antenna connection terminal, the third switch being configured to alternate between coupling the second power amplifier to the second filter and coupling the second power amplifier to the first antenna connection terminal or the second antenna connection terminal.

18. The radio-frequency circuit according to claim 17, configured such that
the second power amplifier is coupled to the first antenna connection terminal or the second antenna connection terminal without involving the second switch and the second filter.

19. The radio-frequency circuit according to claim 1, wherein
each of the first band and the second band is 4G-LTE Band B8, 5G-NR Band n8, 4G-LTE Band B20, 5G-NR Band n20, 4G-LTE Band B26, 5G-NR Band n26, 4G-LTE Band B28, or 5G-NR Band n28.

20. The radio-frequency circuit according to claim 2, wherein
each of the first band and the second band is 4G-LTE Band B8, 5G-NR Band n8, 4G-LTE Band B20, 5G-NR Band n20, 4G-LTE Band B26, 5G-NR Band n26, 4G-LTE Band B28, or 5G-NR Band n28.
